(19) United States
(12) Patent Application Publication
(10) Pub. No.: US 2026/0240025 A1
(43) Pub. Date: Aug. 13, 2026

(54) BALL GRID ARRAY PACKAGE FOR SEMICONDUCTOR DEVICES AND METHODS OF MANUFACTURING SAME

(71) Applicant: STMicroelectronics International N.V., Geneva (CH)

(72) Inventor: Jefferson TALLEDO, Calamba (PH)

(21) Appl. No.: 19/462,755

(22) Filed: Jan. 28, 2026

Related U.S. Application Data
(60) Provisional application No. 63/757,224, filed on Feb. 11, 2025.

(51) Int. Cl. H10W 72/00; H10W 72/20; H10W 74/01

(52) U.S. Cl. CPC H10W 72/012; H10W 72/247; H10W 74/01

(57) ABSTRACT

In accordance with various embodiments of the present disclosure, a method of manufacturing a ball grid array (BGA) package for a semiconductor device is provided, In some embodiments the method comprises disposing a semiconductor die on a top surface of a substrate; disposing a molding compound over the semiconductor die and the top surface of the substrate; disposing a plurality of solder balls on a bottom surface of the substrate; and cutting a slot into the molding compound at each corner of the molding compound, each slot having two opposing ends, each of the two opposing ends of each slot is coincident with a respective one of two adjacent sides of the molding compound.

### CROSS-REFERENCE TO RELATED APPLICATIONS

This application claims priority to and the benefit of US Provisional Patent Application Serial No. 63/757,224, filed February 11, 2025, and titled “BALL GRID ARRAY PACKAGE FOR SEMICONDUCTOR DEVICES AND METHODS OF MANUFACTURING SAME,” which is incorporated herein by reference in its entirety.

### FIELD OF THE INVENTION

Example embodiments of the present disclosure relate generally to packaging for semiconductor devices and, in particular, to ball grid array packaging for semiconductor devices.

### BACKGROUND

Ball grid array (BGA) is a type of surface mount technology that is used for packaging semiconductor devices such as integrated circuits. BGA technology uses a grid of solder balls to conduct electrical signals from the semiconductor device to external devices. BGA packaging for a semiconductor device typically comprises a substrate with conductive traces embedded therein and a semiconductor die attached to the substrate via an adhesive and connected to the conductive traces via wire bonds. The semiconductor die and wire bonds are encapsulated by a molding compound, typically epoxy. A plurality of solder balls are attached to the bottom of the substrate and provide an electrical connection between an external board and the conductive traces (and ultimately the semiconductor die).

Because of thermal stresses that the entire package can be exposed to, the solder ball connections have a tendency to fail in the corners of the package. This is especially true for larger BGA packages. As BGA package size increases, solder joints at the corners of the package experience higher stress, often resulting in lower solder joint life and early solder crack failure.

Applicant has identified many technical challenges and difficulties associated with BGA packaging for semiconductor devices. Through applied effort, ingenuity, and innovation, Applicant has solved problems related to BGA packaging for semiconductor devices by developing solutions embodied in the present disclosure, which are described in detail below.

### BRIEF SUMMARY

Various embodiments described herein related to BGA packages for semiconductor devices, and methods for manufacturing BGA packages for semiconductor devices.

In accordance with various embodiments of the present disclosure, a method of manufacturing a ball grid array (BGA) package for a semiconductor device is provided, In some embodiments the method comprises disposing a semiconductor die on a top surface of a substrate; disposing a molding compound over the semiconductor die and the top surface of the substrate; disposing a plurality of solder balls on a bottom surface of the substrate; and cutting a slot into the molding compound at each corner of the molding compound, each slot having two opposing ends, each of the two opposing ends of each slot is coincident with a respective one of two adjacent sides of the molding compound.

In some embodiments, the slot cut into the molding compound at each corner of the molding compound is disposed at 45 degrees to each of the respective two adjacent sides of the molding compound.

In some embodiments, the molding compound is disposed over the semiconductor die and the top surface of the substrate such that a portion of the molding compound at each corner of the molding compound is thinner than a central portion of the molding compound.

In some embodiments, the molding compound is disposed over the semiconductor die and the top surface of the substrate such that the thinner portion of the molding compound at each corner of the molding compound is generally triangular.

In some embodiments, the molding compound is disposed over the semiconductor die and the top surface of the substrate such that the thinner portion of the molding compound at each corner of the molding compound is generally an isosceles triangle.

In some embodiments, the molding compound is disposed over the semiconductor die and the top surface of the substrate such that the thinner portion of the molding compound at each corner of the molding compound has a thickness that is less than 50 percent of a thickness of the central portion of the molding compound.

In some embodiments, cutting a slot into the molding compound at each corner of the molding compound comprises cutting a slot into the molding compound at each corner of the molding compound using a laser.

In some embodiments, the slot cut into the molding compound at each corner of the molding compound is disposed at an intersection of the molding compound at each corner of the molding compound and the central portion of the molding compound.

In some embodiments, the slot cut into the molding compound at each corner of the molding compound extends down to the substrate.

In some embodiments, the slot cut into the molding compound at each corner of the molding compound does not extend down to the substrate.

In accordance with various embodiments of the present disclosure, a ball grid array (BGA) package for a semiconductor device is provided. In some embodiments the BGA package a substrate, a semiconductor die disposed on a top surface of the substrate, a molding compound disposed over the semiconductor die and the top surface of the substrate, and a plurality of solder balls disposed on a bottom surface of the substrate. The molding compound defines a slot at each corner of the molding compound, each slot having two opposing ends, each of the two opposing ends of each slot being coincident with a respective one of two adjacent sides of the molding compound.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIG. 1 is a perspective view of an example BGA package for a semiconductor device, in accordance with some embodiments of the present disclosure;

FIG. 2 is a top view of the example BGA package for a semiconductor device of FIG. 1; and

FIGS. 3-6 are sectional views illustrating example steps of constructing an example BGA package for a semiconductor device, in accordance with some embodiments of the present disclosure.

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

Various embodiments of the present disclosure overcome the above technical challenges and difficulties and provide various technical improvements and advantages based on, for example, but not limited to, providing a BGA semiconductor package and method of manufacturing a BGA semiconductor package in which portions of the encapsulation/molding material is thinner at the corners and/or diagonal slots are cut into the encapsulation/molding material at the corners to provide flexibility to the package to reduce solder connection failures at the corners.

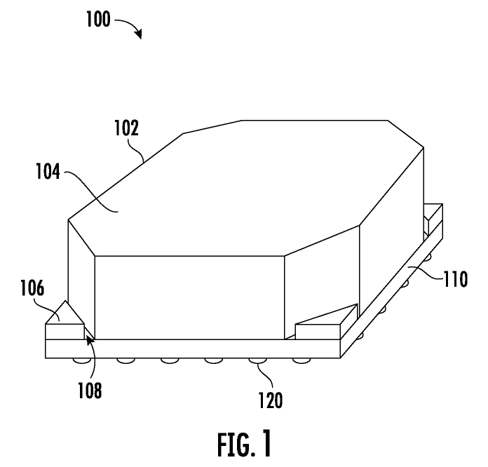

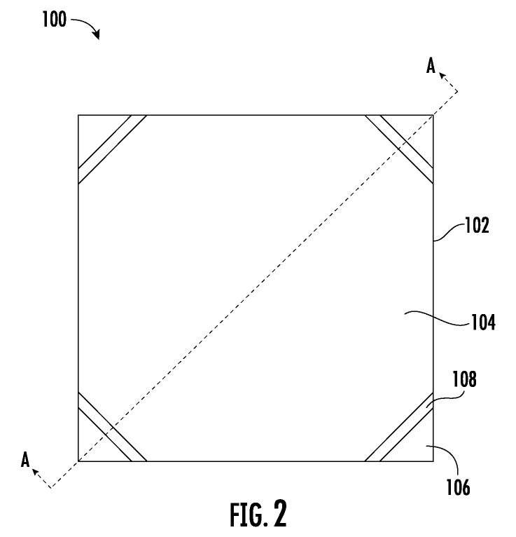

Referring now to the figures, FIG. 1 is a perspective view and FIG. 2 is a top view of an example BGA package 100 for a semiconductor device, in accordance with some embodiments of the present disclosure. The illustrated example BGA package 100 comprises an encapsulation or molding material 102 that encapsulates a semiconductor die (not visible in FIGS. 1 and 2) mounted to a substrate 110. A plurality of solder balls 120 are attached to the bottom surface of the substrate 110.

Conventionally, the molding material in a BGA package would have a uniform thickness. However, in various embodiments of the present disclosure, as seen in the figures, portions 106 of the molding material 102 at the corners are substantially thinner than the central portion 104 of the molding material 102. Additionally, diagonal slots 108 are cut into the molding material 102 at the corners to provide flexibility to the package that will help reduce solder connection failures at the corners. While the figures illustrate a BGA package having both thinner molding material at the corners and slots in the molding material at the corners, various embodiments of the present disclosure may have either thinner molding material at the corners or slots in the molding material at the corners.

As seen in FIGS. 1 and 2, each of the slots 108 span from one side of the BGA molding material 102 to an adjacent side of the molding material 102. In various embodiments, each of the slots cut into the molding material 102 is disposed at 45 degrees to each of the respective two adjacent sides of the molding material 102, such that the thinner portions 106 are generally shaped as isosceles triangles. Any suitable molding material may be used, such as any suitable epoxy. In various embodiments, the thinner portions 106 of the molding material 102 has a thickness that is less than 50 percent of a thickness of the central portion 104.

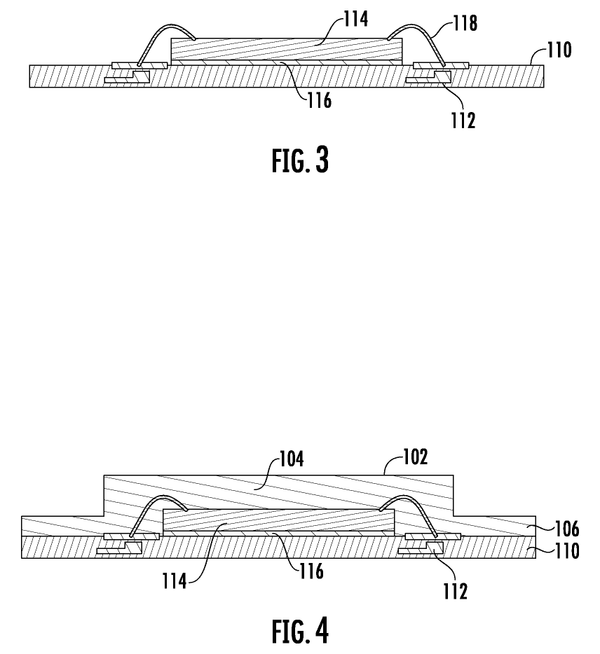

FIGS. 3-6 are sectional views along line A-A of FIG. 2, illustrating example steps of constructing an example BGA package for a semiconductor device in accordance with some embodiments of the present disclosure. Although the figures illustrate the manufacture of a single BGA package, such BGA packages would be manufactured in a matrix of a larger number of BGA packages and then singulated.

In FIG. 3, a semiconductor die 114 has been affixed to a substrate 110, such as via an adhesive 116. The substrate 110 has various conductive traces 112 embedded therein to enable electrical connections between the semiconductor die 114 and the solder balls. The semiconductor die 114 is electrically connected to the conductive traces 112 via wire bonds 118.

In FIG. 4, the semiconductor die 114, the wire bonds 118, and the top surface of the substrate 110 are encapsulated in a molding material 102. The molding material 102 has thinner portions 106 (shown at two opposing corners of the four corners) that is significantly thinner (e.g., less than 50% as thick) than the central portion 104 of the molding material 102. In various embodiments, the molding material 102 may be molded with the thinner portions or the thinner portions may be formed after molding, such as by grinding or laser ablation. Once the molding material 102 has cured, the manufacturing process continues.

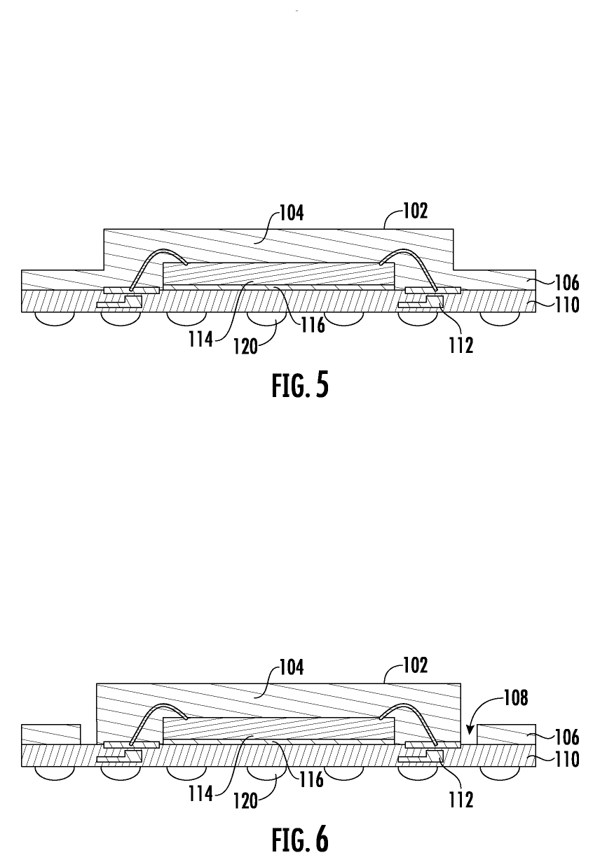

In FIG. 5, the solder balls 120 are attached to the bottom surface of the substrate 110 as conventionally known. The solder balls 120 provide an effective connection point for electrical connections between the semiconductor die 114 and external circuitry (not illustrated).

In FIG. 6, vertical slots 108 are cut or otherwise formed in the molding material 102 at the corners where the thinner portions 106 and thicker central portion 104 of the molding material 102 meet (again, shown at two opposing corners of the four corners). In embodiments in which the molding material does not have thinner portions at the corners, the slots may be cut at any suitable location. In various embodiments, a laser may be used to cut the slots 108, or any other suitable method or mechanism may be used. In various embodiments, the corner slots may also be in another shape (e.g., curve or arc) rather than a straight diagonal cut. In various embodiments, the corner slots take the form of a chamfered cut in which the slot opening at the top (mold side) is wider than the cut at the bottom (substrate side).

In various embodiments, the slots 108 may go all the way to the substrate 110 (i.e., all of the molding material 102 is removed in those areas) or (more likely) a thin layer of the molding material 102 may be left at the bottom of the slots 108.

The thinned molding material and slots in the corners of the molding material of BGA packages of embodiments of the present disclosure provide flexibility/compliance to the corners of the package to better absorb thermomechanical stress, such as during temperature changes. This helps reduce the stress to the solder joints at the package corner, and thus increases board level reliability.

### Conclusion

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

While this detailed description has set forth some embodiments of the present disclosure, the appended claims cover other embodiments of the present disclosure which differ from the described embodiments according to various modifications and improvements. For example, the appended claims can cover any form of semiconductor packaging, including any type of BGA packaging as well as flipchip packaging either in laminate-based or leadframe-based packaging structure.

Within the appended claims, unless the specific term “means for” or “step for” is used within a given claim, it is not intended that the claim be interpreted under 35 U.S.C. 112, paragraph 6.

What is claimed is:

1. A method of manufacturing a ball grid array (BGA) package for a semiconductor device, the method comprising:
disposing a semiconductor die on a top surface of a substrate;
disposing a molding compound over the semiconductor die and the top surface of the substrate;
disposing a plurality of solder balls on a bottom surface of the substrate; and
cutting a slot into the molding compound at each corner of the molding compound, each slot having two opposing ends, each of the two opposing ends of each slot is coincident with a respective one of two adjacent sides of the molding compound.

2. The method of claim 1, wherein the slot cut into the molding compound at each corner of the molding compound is disposed at 45 degrees to each of the respective two adjacent sides of the molding compound.

3. The method of claim 1, wherein the molding compound is disposed over the semiconductor die and the top surface of the substrate such that a portion of the molding compound at each corner of the molding compound is thinner than a central portion of the molding compound.

4. The method of claim 3, wherein the molding compound is disposed over the semiconductor die and the top surface of the substrate such that the thinner portion of the molding compound at each corner of the molding compound is generally triangular.

5. The method of claim 4, wherein the molding compound is disposed over the semiconductor die and the top surface of the substrate such that the thinner portion of the molding compound at each corner of the molding compound is generally an isosceles triangle.

6. The method of claim 3, wherein the molding compound is disposed over the semiconductor die and the top surface of the substrate such that the thinner portion of the molding compound at each corner of the molding compound has a thickness that is less than 50 percent of a thickness of the central portion of the molding compound.

7. The method of claim 3, wherein cutting a slot into the molding compound at each corner of the molding compound comprises cutting a slot into the molding compound at each corner of the molding compound using a laser.

8. The method of claim 3, wherein the slot cut into the molding compound at each corner of the molding compound is disposed at an intersection of the molding compound at each corner of the molding compound and the central portion of the molding compound.

9. The method of claim 3, wherein the slot cut into the molding compound at each corner of the molding compound extends down to the substrate.

10. The method of claim 3, wherein the slot cut into the molding compound at each corner of the molding compound does not extend down to the substrate.

11. A ball grid array (BGA) package for a semiconductor device comprising:
a substrate;
a semiconductor die disposed on a top surface of the substrate;
a molding compound disposed over the semiconductor die and the top surface of the substrate; and
a plurality of solder balls disposed on a bottom surface of the substrate;
wherein the molding compound defines a slot at each corner of the molding compound, each slot having two opposing ends, each of the two opposing ends of each slot being coincident with a respective one of two adjacent sides of the molding compound.

12. The BGA package of claim 11, wherein the slot defined by the molding compound at each corner of the molding compound is disposed at 45 degrees to each of the respective two adjacent sides of the molding compound.

13. The BGA package of claim 11, wherein a portion of the molding compound at each corner of the molding compound is thinner than a central portion of the molding compound.

14. The BGA package of claim 13, wherein the thinner portion of the molding compound at each corner of the molding compound is generally triangular.

15. The BGA package of claim 14, wherein the thinner portion of the molding compound at each corner of the molding compound is generally an isosceles triangle.

16. The BGA package of claim 13, wherein the thinner portion of the molding compound at each corner of the molding compound has a thickness that is less than 50 percent of a thickness of the central portion of the molding compound.

17. The BGA package of claim 13, wherein the slot defined by the molding compound at each corner of the molding compound is laser-cut.

18. The BGA package of claim 13, wherein the slot cut defined by the molding compound at each corner of the molding compound is disposed at an intersection of the thinner portion of the molding compound at each corner of the molding compound and the central portion of the molding compound.

19. The BGA package of claim 13, wherein the slot defined by the molding compound at each corner of the molding compound extends down to the substrate.

20. The BGA package of claim 13, wherein the slot defined by the molding compound at each corner of the molding compound does not extend down to the substrate.
